(19) United States
(12) Patent Application Publication
(10) Pub. No.: US 2010/0120199 A1
(43) Pub. Date: May 13, 2010

(54) Stacked package-on-package semiconductor device and methods of fabricating thereof

(76) Inventors: Bok Sim Lim, Penang (MY); A. Vethanayagam Rudge, Penang (MY)

Correspondence Address: INTEL CORPORATION;c/o CPA Global, P.O. BOX 52050, MINNEAPOLIS, MN, 55402, US

(21) Appl. No.: 12/291,292

(22) Filed: Nov. 7, 2008

(51) Int. Cl. H01L 21/00

(52) U.S. Cl. 438/109; 257/E21.001

(57) ABSTRACT

Methods for fabricating a semiconductor package are provided, by coupling a plurality of first interconnects and a semiconductor die to a first surface of a substrate, and depositing a mold material on the first surface by compression molding to fully encapsulate the die and to partially encapsulate the first interconnects.

### BACKGROUND

1. Technical Field

Embodiments of the invention relate generally to semiconductor assemblies, and more particularly, to stacked package-on-package (PoP) integrated circuit (IC) assemblies and methods for manufacturing the same.

2. Description of Related Art

With an increased demand for smaller and lighter electronic products with more functionalities and higher performance, package-on-package (PoP) assemblies are experiencing strong growth. By capitalizing on the volumetric packaging benefits of stacking devices for integrating complex logic and memory devices, PoP offers significant advantages related to the reduction of product form factor.

In a typical PoP assembly, a top package is connected to a bottom package through exposed leads formed on a top surface of the bottom package such that the top and bottom packages may be operable as a unit. The PoP arrangement improves device testability by allowing separate testing of logic and memory packages before they are assembled in a PoP stack. The electrical performance of the associated packages in the PoP stack may also be improved due to the shortened interconnections therebetween.

A key challenge in a PoP assembly is minimizing thickness of the PoP assembly yet preventing warpage of individual layers forming the packages. Warpage of the individual layers leads to problems such as fractures, separation of solder joints and the layers, and open or short circuits caused by separation of materials or by the ingress of moisture between the separated materials. In addition, warpage may occur at the non-molded areas of the packages, e.g. edges and corners.

### BRIEF DESCRIPTION OF THE DRAWINGS

Embodiments of the invention are disclosed hereinafter with reference to the drawings, in which:

FIG. 1 is a perspective view of a bottom package of a package-on-package (PoP) assembly according to one embodiment of the invention;

FIG. 2 is a cross-sectional view of the bottom package shown in FIG. 1.

FIG. 3 is a flow sequence of fabricating a bottom package according to one embodiment of the invention; and

FIGS. 4A to 4D illustrate various process outputs obtained during the flow sequence of FIG. 3.

### DETAILED DESCRIPTION

In the following description, numerous specific details are set forth in order to provide a thorough understanding of various illustrative embodiments of the invention. It will be understood, however, to one skilled in the art, that embodiments of the invention may be practiced without some or all of these specific details. In other instances, well known process operations have not been described in detail in order not to unnecessarily obscure pertinent aspects of embodiments being described. In the drawings, like reference numerals refer to same or similar functionalities or features throughout the several views.

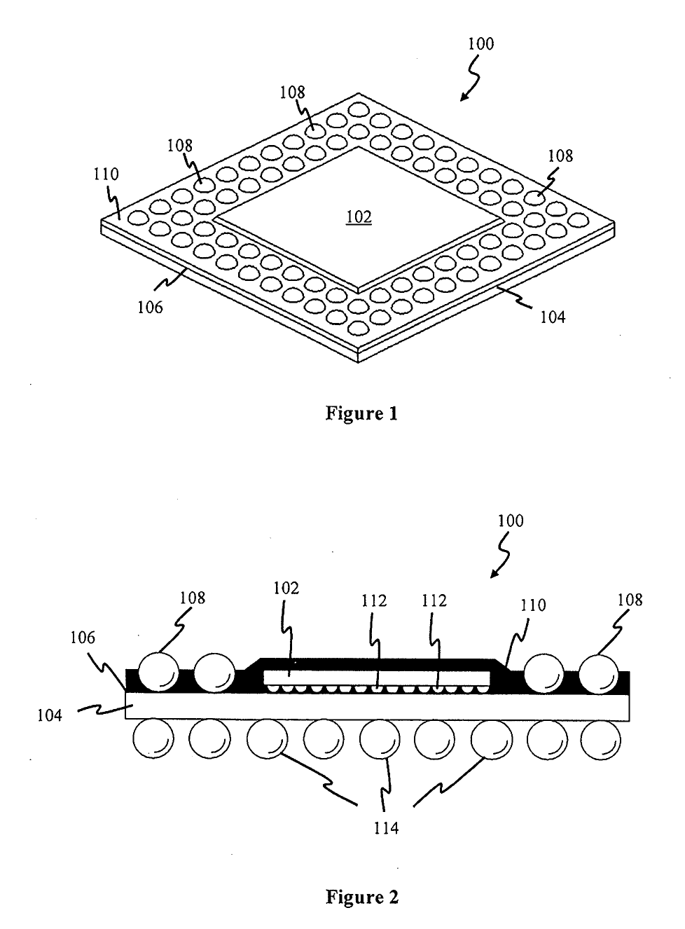

FIG. 1 shows a perspective view of a bottom package 100 of a package-on-package (PoP) assembly according to one embodiment of the invention. A cross-sectional view of the bottom package 100 is shown in FIG. 2. A top package (not shown) may be mounted on the bottom package 100 to form the complete PoP assembly. If required, it is to be understood that embodiments of the invention may be applicable to a top package or to an intermediate package of an assembly with suitable modifications.

The bottom package 100 comprises a die 102 mounted to a first (or top) surface 106 of a substrate 104 having a plurality of first conductive interconnects 108 disposed on the first surface 106 of the substrate 104. The die 102 may implement various types of memory devices or logic processor devices. In one embodiment, the die 102 is an integrated circuit (IC) chip. In alternative embodiments, a plurality of dies 102 may be mounted to the first surface 106 of the substrate 104. Examples of the substrate 104 include, but are not limited to, a direct layer and lamination (DLL3) substrate, a coreless substrate, or a substrate having four or less layers. The first interconnects 108 may be disposed on the periphery of the first surface 106 surrounding the die 102. More particularly, the first interconnects 108 may be disposed on portions of the first surface 106 that are not used or reserved for mounting the die 102. The first interconnects 108 may also be referred to as conductive bumps or solder balls comprising a solder material, e.g. a lead/tin alloy, copper or a combination thereof. An encapsulation film 110 is provided which fully encapsulates the die 102 and partially encapsulates the first interconnects 108 to expose an upper portion of the first interconnects 108.

The die 102 may be flip chip, ball grid array (BGA) or other types, with under-die interconnects 112 provided on an under-side of the die 102 to electrically couple the die 102 to the substrate 104. An underfill material may be provided in a region between the die 102 and the substrate 104 to protect the under-die interconnects 112 from the environment.

The first interconnects 108 are to enable electrical coupling of the bottom package 100 to a separate component or another package, e.g. a memory package to form a PoP). More particularly, the exposed upper portions of the first interconnects 108 are to be coupled to a top package in a PoP assembly.

A plurality of second conductive interconnects 114 may be provided on a second (or bottom) surface of the substrate 104 to facilitate electrical coupling of the substrate 104 to a separate component, e.g., motherboard or system board. This would enable both the top package and bottom package 100 (i.e. the PoP assembly) to be operable as a unit thereafter.

According to one embodiment of the invention, a mold material that forms the encapsulation film 110 is provided to fully encapsulate the die 102 and partially encapsulate the first interconnects 108. The mold material that forms the encapsulation film 110 may be a thermosetting material such as epoxy or polymer resin which may contain varying amounts (e.g. 0% to 80% by weight) of silica, alumina, or other suitable inorganic particles. In certain other embodiments, the thermosetting material may contain fluxes to provide fluxing capabilities during subsequent reflow processes. As illustrated in FIG. 2, a thickness of the mold material that forms the encapsulation film 110 is less than a height of the first interconnects 108 to expose upper portions of the first interconnects 108. The encapsulation film 110, however, should have sufficient thickness to fully encapsulate the die 102 and to stiffen the substrate 104.

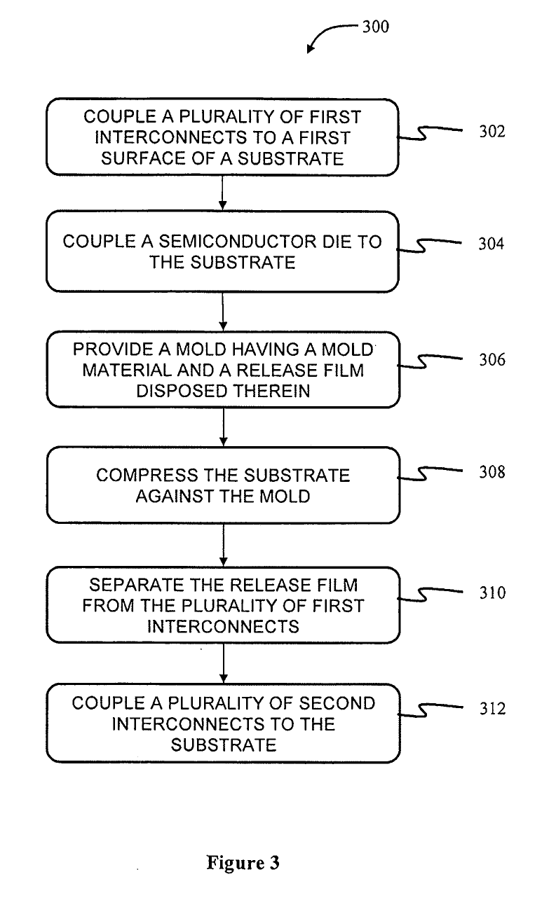

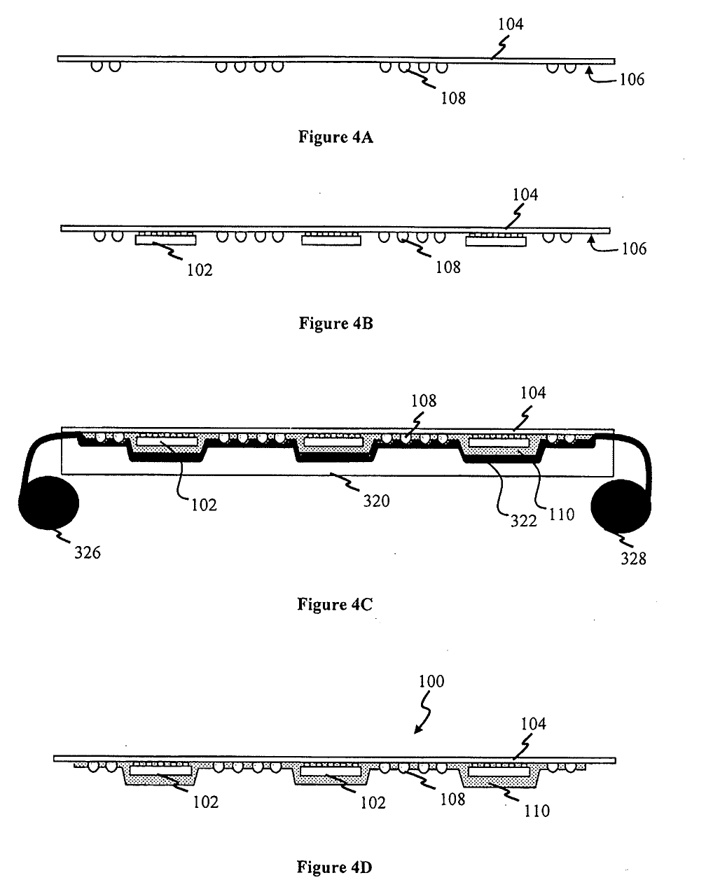

FIG. 3 is a flow sequence 300 for a method of fabricating the package 100 according to one embodiment of the invention. The flow sequence 300 will be described with further reference to FIGS. 4A to 4D illustrating various process outputs obtained during the flow sequence 300 of FIG. 3.

The flow sequence 300 begins with coupling a plurality of first interconnects 108 to a first surface 106 of a substrate 104 using known methods (block 302, FIG. 4A). The first interconnects 108 may be suitably arranged to form a periphery around a semiconductor die 102 to be mounted on the substrate 104. A semiconductor die 102 may then be coupled or mounted on the substrate 104 using known methods (block 304, FIG. 4B). It is to be appreciated that the sequence for coupling the first interconnects 108 and the semiconductor die 102 to the substrate 104 may be interchanged without altering the invention.

The flow sequence 300 subsequently proceeds to a compression molding process to deposit a mold material that forms the encapsulation film 110 on the first surface 106 of the substrate 104. To this purpose, a suitable mold 320 is provided which has mold cavities appropriately shaped to conform to an arrangement of the semiconductor die 102 and the first interconnects 108 on the substrate 102 (block 306). The mold 320 has a release film 322 and a mold material that forms the encapsulation film 110 disposed therein. Reference numeral 326 designates a film feeding roller for feeding release film 322 onto the mold 320, while 328 designates a film take-up roller for the release film 322. As illustrated in FIG. 4C, the film feeding roller 326 and film take-up roller 328 are located on opposite sides of the mold 320. In such an arrangement, the release film 322 moves from one side to another side of the mold 320. The release film 322 may be shaped to conform to the mold cavities using air suction. After the release film 322 is conformed to the mold cavities, a mold material that forms the encapsulation film 110 is dispensed on the release film 322 to form a juxtaposed layer to the release film 322. The mold material that forms the encapsulation film 110 may be provided in a granular or powdered form, examples of which include, but are not limited to, a thermosetting material and a polymer resin. The release film 322 may include an epoxy base material or other suitable materials. A thicker mold material that forms the encapsulation film 110 is required to fully encapsulate a semiconductor die 102 while a less thick mold material that forms the encapsulation film 110 is required to partially encapsulate the first interconnects 108. Accordingly, the release film 322 provided in the cavities may have a relatively constant thickness while the mold material that forms the encapsulation film 110 provided in the cavities may have a varied thickness.

During molding, the substrate 104, together with the die 102 and the first interconnects 108 coupled thereto, is compressed against the mold 320 and more particularly the juxtaposed arrangement of the release film 322 and mold material that forms the encapsulation film 110 (block 308, FIG. 4C). During compression, the release film 322 squeezes the mold material that forms the encapsulation film 110 away from the first interconnects 108 until the first interconnects 108 are partially encapsulated by the mold material that forms the encapsulation film 110. More particularly, the release film 322 should be in contact with or overlaying portions of the first interconnects 108 such that the first interconnects 108 are spread across the release film 322 and the mold material that forms the encapsulation film 110. The foregoing steps should be performed at suitable temperatures to enable cross-linking of the mold material that forms the encapsulation film 110.

Subsequently, the release film 322 is separated or removed from the first interconnects 108 (block 310, FIG. 4D). Upon separation, the encapsulation film 110 remains coupled to the substrate 104 to fully encapsulate the die 102 while partially encapsulating the first interconnects 108 to expose portions of the first interconnects 108. At this stage, a thickness of the encapsulation film 110 may be greater than the height of the die 102 but less than the height of the first interconnects 108. In addition to separating the release film 322 from the first interconnects 108, an excess of the mold material 322 may be removed from the first interconnects 108, using suitable cleaning methods, to reduce contamination of the first interconnects 108.

The sequence 300 may proceed to coupling a plurality of second interconnects 114 to a second (or bottom) surface of the substrate 104 using known methods (block 312, FIG. 4D). Subsequently, the package 100 may be rendered for further processing, e.g. singulation.

Embodiments of the invention are useful in providing low cost substrate stiffening of the substrate without increasing keep-out-zone (KOZ) or thickness of the substrate. With a stiffened substrate, a likelihood of package warpage is reduced. This is useful to achieve reduced package sizes by using thin substrates, e.g. DLL3 substrates, coreless substrates and substrates having four or less layers. Further with the stiffened substrate, a need for handling media in downstream assembly of thin substrate is also reduced. These uses would result in an increased demand for coreless DLL3 substrates, coreless or thin substrates for flip chip processing, as well as significant cost savings associated with coreless and thin substrate technology.

Other embodiments will be apparent to those skilled in the art from consideration of the specification and practice of the invention. Furthermore, certain terminology has been used for the purposes of descriptive clarity, and not to limit the disclosed embodiments of the invention. The embodiments and features described above should be considered exemplary, with the invention being defined by the appended claims.

1. An article comprising:
a film first dielectric including a first dielectric first surface and a first dielectric second surface, wherein the film first dielectric has a first dielectric constant;
a second dielectric disposed adjacent the film first dielectric, wherein the second dielectric includes a second dielectric boundary that is substantially coplanar with the first dielectric first surface, wherein the second dielectric has a second dielectric constant that is smaller than the first dielectric constant; and
a spiral inductor first electrode disposed above the film first dielectric and the second dielectric, wherein the spiral inductor first electrode includes a first electrode first surface and a first electrode second surface that is parallel planar with the first electrode first surface, and wherein the first electrode second surface is at the second dielectric boundary.

2. The article of claim 1, wherein the spiral inductor first electrode is entirely supported by the second dielectric.

3. The article of claim 1, wherein the spiral inductor first electrode is partially supported by the film first dielectric at the first dielectric first surface.

4. The article of claim 1, wherein the second dielectric is a gas.

5. The article of claim I, wherein the second dielectric is a gas selected from air, nitrogen, oxygen, argon, a noble gas, and combinations thereof.

6. The article of claim 1, wherein the second dielectric is a solid selected from an organic, an inorganic, and a combination thereof.

7. The article of claim 1, further including a ground film disposed below the first dielectric second surface.

8. The article of claim 1, further including a ground film disposed below the first dielectric second surface, wherein the spiral inductor first electrode includes a first terminal and a second terminal, wherein the second terminal is coupled to a trace disposed coplanar with the ground film.

9. The article of claim 1, further including a spiral inductor second electrode disposed above the spiral inductor first electrode and coupled to the first terminal and the second terminal.

10. A process comprising:
forming a spiral inductor first electrode above a substrate, wherein the substrate includes a patterned film first dielectric and a second dielectric disposed in the patterned film first dielectric, wherein the film first dielectric includes a first dielectric first surface and a first dielectric second surface, wherein the second dielectric is disposed adjacent the film first dielectric, wherein the second dielectric includes a second dielectric boundary that is substantially coplanar with the first dielectric first surface;
wherein the film first dielectric and the second dielectric are below the spiral inductor, and wherein forming the spiral inductor first electrode occurs more directly above the second dielectric than directly above the film first dielectric.

11. The process of claim 10, wherein forming the patterned film first dielectric includes:
forming a recess in the film first dielectric to achieve the patterned film first dielectric, wherein the film first dielectric has a first dielectric constant;
filling the recess with the second dielectric, wherein the second dielectric has a second dielectric constant that is smaller than the first dielectric constant.

12. The process of claim 11, wherein forming the recess is a process selected from imprinting a B-staged polymer as the film first dielectric, imprinting the film first dielectric, etching the film first dielectric, and combinations thereof.

13. The process of claim 11, wherein filling the recess is selected from filling the recess with a gas, a paste, and a solid.

14. The process of claim 10, further including laminating the film first dielectric with a ground film, wherein the film first dielectric includes a first side and a second side, wherein the spiral inductor first electrode is disposed above the first side and the ground film is disposed below the second side.

15. The process of claim 10, further including:
laminating the film first dielectric with a ground film, wherein the film first dielectric includes a first side and a second side, wherein the spiral inductor first electrode is disposed above the first side and the ground film is disposed below the second side; and
forming a trace coplanar with the ground film.

16. The process of claim 10, further including packaging the spiral inductor first electrode with a microelectronic device.

17. The process of claim 10, further including forming a spiral inductor second electrode above the spiral inductor first electrode.

18. A system comprising:
a film first dielectric including a first dielectric first surface and a first dielectric second surface, wherein the film first dielectric has a first dielectric constant;
a second dielectric disposed adjacent the film first dielectric, wherein the second dielectric includes a second dielectric boundary that is substantially coplanar with the first dielectric first surface, wherein the second dielectric has a second dielectric constant that is smaller than the first dielectric constant; and
a spiral inductor first electrode disposed above the film first dielectric and the second dielectric, wherein the spiral inductor first electrode includes a first electrode first surface and a first electrode second surface that is parallel planar with the electrode first surface, and wherein the electrode second surface is at the second dielectric boundary;
a die coupled to the spiral inductor first electrode; and
dynamic random-access memory coupled to the die.

19. The system of claim 18, further including a spiral inductor second electrode disposed above the spiral inductor first electrode.

20. The system of claim 18, wherein the die and the spiral inductor are disposed in a single package.

21. The system of claim 18, wherein the system is disposed in one of a computer, a wireless communicator, a hand-held device, an automobile, a locomotive, an aircraft, a watercraft, and a spacecraft.

22. The system of claim 18, wherein the die is selected from a data storage device, a digital signal processor, a micro controller, an application specific integrated circuit, and a microprocessor.
